(19) United States
(12) Patent Application Publication
(10) Pub. No.: US 2025/0372952 A1
(43) Pub. Date: Dec. 4, 2025

(54) LASER SENSOR AND METHOD OF MANUFACTURING A LASER SENSOR

(71) Applicant: ams International AG, Jona (CH)

(72) Inventors: Laurent NEVOU, Wadenswil (CH); Marcelli GRIMAU, Adliswil (CH); Svenja MAUTHE, Altendorf (CH); Jens GEIGER, Thalwil (CH)

(21) Appl. No.: 19/105,138

(22) PCT Filed: Aug. 2, 2023
(86) PCT No.: PCT/EP2023/071396

§ 371 Date: Feb. 20, 2025

(30) Foreign Application Priority Data
Aug. 22, 2022 (DE) 10 2022 121 114.2

(51) Int. Cl. H01S 5/183; G01B 9/02; H01S 5/026

(52) U.S. Cl. CPC H01S 5/18355; G01B 9/02092; H01S 5/0264; H01S 5/18305; G01B 2290/70

(57) ABSTRACT

A self-mixing interferometric (SMI) laser sensor includes a vertical cavity surface emitting laser (VCSEL) configured to emit laser radiation with a linear polarization through an emission surface. The SMI laser sensor also includes a photodetector configured to monitor the laser radiation of the VCSEL. The SMI laser sensor further includes a linear polarizer arranged in front of the photodetector such that the laser radiation passes through the linear polarizer before reaching the photodetector. An orientation of a passing polarization of the linear polarizer differs from the linear polarization of the laser radiation of the VCSEL by an angle different from zero.

This disclosure relates to a self-mixing interferometric laser sensor, to an electronic device comprising such a laser sensor, and to a manufacturing method of an SMI laser sensor.

### BACKGROUND OF THE INVENTION

Optical self-mixing interferometry (SMI) sensors provide the possibility of measuring absolute and relative distances as well as vibrations and velocities of objects and thus enable an employment in a wide range of applications. This can mean that SMI sensors can be employed in a wide range of applications. Therein, SMI laser sensors rely on the interferometric effect of laser light, which is reflected or scattered back from an object or a scene in the field-of-view of the sensor and re-enters the laser cavity, with the resonating radiation inside the cavity. As a result, the output properties of the laser, such as the output power and a junction voltage, are influenced by the self-mixing interference. In particular, the resulting output power or frequency variations contain traceable information on the movement or distance of the target object with respect to the sensor.

State-of-the-art SMI laser sensors typically employ semiconductor lasers as the light source, for instance as their light source. The effective cavity length in such devices commonly depends on an applied current via the temperature of the laser device. In particular, the output frequency of semiconductor lasers basically instantaneously follows any current variations due to the simultaneously changed optical resonator length. Hence, by applying a defined current shape, e.g. a periodic saw tooth or triangular current, the resulting difference in frequency between the resonating and the back-scattered light can be evaluated in a suitable evaluation unit and translated back to a desired position or velocity information, for instance.

Vertical-cavity surface-emitting lasers, VCSELs, being the most prominent choice in SMI sensors, comprise a gain region that is sandwiched between two distributed Bragg reflectors, DBR, acting as end mirrors and for feeding current into the gain region. Typically, one of the DBRs is highly reflective with a reflectivity in excess of 99.9%, while the other has a lower reflectivity for enabling out coupling of light through an emission surface of the VCSEL. In an SMI sensor, this lower reflectivity DBR also serves as input port for the laser light that is received from the object or scene such that the light can be reinjected into the cavity via the emission surface. VCSELs have the advantage that their surface-emitting properties render them suitable for production and testing on a wafer level in large quantities, which opens the possibility of a low-cost production process. Furthermore, the output power can be scaled to a certain extent via the area of the emitting surface.

For the actual SMI measurement, the frequency of the VCSEL is tuned via applying the aforementioned modulated drive current, e.g. a drive current having an AC component, e.g. a saw tooth modulation, on top of a DC component. The self-mixing interference is detected and measured via the output power of the VCSEL via a photodetector that picks up a portion of the emitted light. The signal contribution due to the modulation, which is often significantly larger than the SMI contribution, has to be subtracted from the generated photo signal data in order to gain access to the useful SMI contribution of the photo signal.

Current approaches to remove the modulation contribution take place via post processing or via hardware demodulation. However, both of these ways are very challenging because a hardware solution often introduces additional noise, while the post processing requires a large amount of ADC bits and a low gain amplification. In summary, both of these approaches lead to a significantly reduced signal-to-noise ratio of the wanted SMI signal.

Thus, it is an object to be achieved to provide an SMI laser sensor with efficient removal of the modulation signal that overcomes the limitations of state-of-the-art devices. It is further an object to provide a manufacturing method of such an SMI laser sensor.

These objects are achieved with the subject matter of the independent claims. Further developments and embodiments are described in the dependent claims.

### SUMMARY OF THE INVENTION

This disclosure overcomes the above-mentioned technical limitations by providing a SMI laser sensor that removes the contribution of the photo signal caused by the current modulation in the optical domain. Therein, use is made of the fact that, due to their architecture, VCSEL devices emit linearly polarized light while being operated in a single-mode domain, which is desirable for SMI measurements in the first place. For removing the modulation from the detected signal, a cross polarizer is employed that has a passing polarization which is rotated, e.g. it is perpendicular, with respect to the linear polarization emitted by the VCSEL. This way, the modulation can be efficiently suppressed and prevented from reaching the photodetector such that the detected signal merely consists of the wanted contribution due to self-mixing interference.

Specifically, a self-mixing interferometry laser sensor comprises a vertical cavity surface emitting laser, VCSEL, configured to emit laser radiation with a linear polarization through an emission surface, a photodetector configured to monitor the laser radiation of the VCSEL, and a linear polarizer arranged in front of the photodetector such that the laser radiation passes through the linear polarizer before reaching the photodetector. An orientation of a passing polarization of the linear polarizer differs from the linear polarization of the laser radiation of the VCSEL by an angle different from zero.

The VCSEL has a vertical laser cavity that is formed between the front side of the first DBR and the back side of the second DBR. In other words, the first and second DBRs act as end mirrors with the laser cavity being formed by the cavity region that is sandwiched in between. In particular, the cavity region can be sandwiched between the first DBR and the second DBR. The cavity region comprises an active light generation region that is formed by an active laser medium, often also called a gain medium, as the source of optical gain required in a laser. The VCSEL emits electromagnetic radiation through a partially transmissive end mirror, e.g. through the second DBR such that a top side of the second DBR facing away from the cavity region acts as emission surface. Therein, the first and second DBR are designed for a specific emission wavelength or emission wavelength range of the 5 VCSEL.

The VCSEL is configured to undergo self-mixing interference in its cavity. This means that light that is emitted by the VCSEL through the emission surface and reflected or scattered by an object or a scene arranged distant to the laser sensor can re-enter the laser cavity via re-injection through the emission surface, causing the self-mixing interference. Self-mixing interference in turn causes an alteration, e.g. modulation, of the optical power in the laser cavity and thus of the laser output power. This effect of the self-mixing interference can be monitored via the above-mentioned optional photodetector. Alternatively or in addition, the SMI can be detected via electrical properties of the VCSEL, e.g. a bias current or a junction voltage.

The photodetector, e.g. comprising a photodiode that is photosensitive at the emission wavelength of the VCSEL, is arranged such that it detects a portion of the light emitted by the VCSEL. If the VCSEL is characterized by two-sided emission, the photodetector can be arranged facing a further emission surface of the VCSEL. Alternatively, a portion of the light emitted through the emission surface can be directed to the photodetector via a beam splitting element, for instance.

The linear polarizer is arranged in front of a photosensitive surface of the photodetector, for instance, and has a passing polarization that is rotated with respect to a polarization of the light emitted by the VCSEL. In other words, the passing polarization is different from the linear polarization of the emitted light. In this way, the signal due to self-mixing interference passes through the polarizer while the signal due to the current modulation can be partially or fully rejected. The suppression of the modulation is thus realized completely in the optical domain without the need for further hardware or post-processing. For example, the linear polarizer is directly disposed on a photosensitive surface of the photodetector.

In some embodiments, the passing polarization of the linear polarizer is orthogonal to the linear polarization of the laser radiation of the VCSEL. The modulation of the driving current typically leaves the polarization of the emitted light unchanged as long as the VCSEL remains in single mode. As the signal due to SMI, however, typically alters a polarization of the emitted light, the linear polarizer can be set to have a passing polarization that is orthogonal to said polarization of the emitted light. This leads to the fact that the modulation is rejected, while the optical signal carrying a self-mixing interference signature can reach the photodetector and thus be detected.

In some embodiments, the linear polarizer is an absorptive polarizer. This type of polarizer is configured to absorb unwanted polarization states, e.g. the polarization state emitted by the VCSEL. Examples of such polarizers include crystals that exhibit dichroism, i.e. the preferential absorption of light which is polarized in particular directions. Modern absorptive polarizers are typically formed from nanoparticles, such as silver nanoparticles, embedded in a thin transparent substrate, e.g. glass. Such structures are capable of achieving polarization ratios as high as 100,000:1 and an absorption of correctly polarized light as low as 1.5%. These type of polarizers are commonly used in the near-infrared domain in applications such as optical fiber communication. Absorptive polarizers in an SMI sensor can help to suppress unwanted stray light from being internally reflected, for instance.

Alternatively, the linear polarizer is a beam-splitting polarizer. This type of polarizer is configured to split the incident beam into two beams of differing linear polarization. For example, the beam-splitting polarizer is ideal and outputs fully polarized light at orthogonal polarizations. Alternatively, only one of the two output beams is fully polarized, while the other contains a mixture of polarization states. Ideal beam-splitting polarizers can be employed in an SMI sensor to direct the light directed toward the photodetector, but to be rejected by the polarizer, to the scene or the object the distance is determined to in order to increase the overall SNR by enhancing the self-mixing interference. For example, this can mean that the beam-splitting polarizer can be employed to direct the light directed towards the photodetector to the scene or the object for which the distance is determined. Examples of beam-splitting polarizers include Fresnel polarizers, birefringent polarizers, thin film polarizers, and wire-grid polarizers, for instance.

In some embodiments, the photodetector is configured to detect changes in properties of the emitted laser radiation, in particular in the emitted light intensity, due to self-mixing interference. As aforementioned, light that is reflected from an object or a scene and reinjected into the laser cavity can cause the buildup of self-mixing interference. To this end, the laser frequency is swept by means of current modulation such that standing waves of the light within the cavity and the reinjected light can be formed. Meeting this condition significantly influences the emitted output power of the VCSEL such that the presence and degree of self-mixing interference can easily be determined via monitoring of the output intensity of the VCSEL. Thus, the photodetector is configured to monitor alterations in the emitted optical power and generate a photo signal comprising information of these alterations. The photo signal can be provided to an evaluation unit, comprised by the SMI sensor or external, for analysis and distance determination, for instance. Here, “external” can mean that the evaluation unit is not comprised by the SMI sensor. For instance, the SMI sensor can be free of the evaluation unit. This can mean that the evaluation unit is an external device.

In some embodiments, the VCSEL is characterized by two-sided emission through the emission surface and a further emission surface opposite the emission surface. Moreover, the photodetector is arranged to capture laser radiation emitted through the further emission surface. A VCSEL with two-sided emission makes monitoring the output power via a second emission surface, e.g. through a back side of the VCSEL, straightforward. For example, the VCSEL is arranged on a substrate body, which includes a photodetector on or within a top surface such that the back side of the VCSEL is arranged above the photodetector. In this way, the output power fluctuations due to SMI can be easily monitored as SMI influences the emission of the VCSEL on both sides in the same manner.

In some embodiments, the SMI laser sensor further comprises a beam splitter that is arranged on or distant from the emission surface. Said beam splitter is configured to transmit a portion of the emitted light to an object or a scene, and reflect a remaining portion of the emitted light toward the linear polarizer and photodetector. Particularly, in embodiments in which the VCSEL is characterized by single-sided emission, the monitoring of the output power can be realized by means of directing a small fraction of the emitted light from a main beam path oriented between the VCSEL and the scene or object, onto a monitoring beam path toward the photodetector by means of a non-polarizing beam splitter. For example, the beam splitter is configured to direct a small fraction, e.g. less than 1% or 10%, of the emitted light intensity onto the monitoring beam path toward the photodetector while the remainder of the emitted light is transmitted and thus is directed to the object or scene. The beam splitter can be a beam splitter cube formed from two triangular prisms, for instance. The beam splitter does not alter a polarization of the emitted light.

In some embodiments, the SMI laser sensor further comprises a transparent cover that is arranged distant from the emission surface and configured to transmit a portion of the emitted light to an object or a scene, and to reflect a remaining portion of the emitted light toward the linear polarizer and photodetector. Instead of a beam splitter, the SMI laser sensor can comprise a cover glass which is mostly transmissive, however, reflects a small portion, e.g. less than 1% or 10%, of the emitted light to the photodetector.

In some embodiments, the SMI laser sensor further comprises an evaluation unit coupled to the photodetector and configured to determine an absolute distance, a relative distance, and/or a velocity of an object distant to the SMI laser sensor from a photodetector signal. The photo signal generated by the photodetector carries information of the self-mixing interference formed in the laser cavity. The evaluation unit receives the photo signal and extracts said information, from which an absolute or relative distance, a velocity or a vibration of an object distant to the laser sensor can be determined from. To this end, the evaluation unit, e.g. realized as an integrated circuit, is electrically coupled to the photodetector.

In some embodiments, the SMI laser sensor further comprises a further linear polarizer arranged in front of the photodetector such that the laser radiation passes through the linear polarizer and the further linear polarizer before reaching the photodetector. In order to suppress the modulation to an even higher degree, a stack of two or more linear polarizers can be arranged in front of the photodetector, such that an imperfection of the first polarizer is compensated for. Ideally, an orientation of a passing polarization of the further linear polarizer equals the orientation of the passing polarization of the linear polarizer. In other words, the passing polarizations of the linear polarizer and the further linear polarizer are parallel to each other.

In some embodiments, an orientation of a passing polarization of the linear polarizer is adjustable. In order to account for polarization drifts of the laser, e.g. due to aging or contamination of the emission surface, the passing polarization of the linear polarizer can be made adjustable such that said drifts can be accounted for by keeping the passing polarization of the polarizer orthogonal to the polarization of the emitted light, for instance.

In some embodiments, the SMI laser sensor further comprises an optical grating arranged on the emission surface. An optical grating arranged on the emission surface can ensure a stable and/or predetermined polarization of the emitted light to an even higher degree and particularly at a larger current range, at which potentially higher order modes start to lase.

Moreover, an electronic device comprising a SMI laser sensor according to one of the above-mentioned embodiments is provided, wherein the SMI laser sensor is configured to measure an absolute distance, a relative distance, and/or a velocity of an object distant from the electronic device in the field-of-view of the SMI laser sensor. The electronic device can be a mobile or portable device including a smartphone, a tablet computer, a laptop computer or a wearable accessory such as a smart wristband, a smartwatch or an earphone device.

Moreover, a method of manufacturing a SMI laser sensor is provided. The method comprises providing a vertical cavity surface emitting laser, VCSEL, which is configured to emit laser radiation with a linear polarization through an emission surface. The method further comprises arranging a photodetector for monitoring the laser radiation of the VCSEL, and arranging a linear polarizer in front of the photodetector such that the laser radiation passes through the linear polarizer before reaching the photodetector. Therein, an orientation of a passing polarization of the linear polarizer differs from the linear polarization of the laser radiation of the VCSEL by an angle different from zero.

For example, the orientation of the passing polarization of the linear polarizer is orthogonal to the linear polarization of the laser radiation of the VCSEL.

Further embodiments of the method become apparent to the skilled reader from the aforementioned embodiments of the SMI laser sensor and the electronic device, and vice-versa.

### BRIEF DESCRIPTION OF THE DRAWINGS

The following description of figures may further illustrate and explain aspects of the SMI laser sensor and the method of manufacturing an SMI laser sensor. Components and parts of the SMI laser sensor that are functionally identical or have an identical effect are denoted by identical reference symbols. Identical or effectively identical components and parts might be described only with respect to the figures where they occur first. Their description is not necessarily repeated in successive figures.

### DETAILED DESCRIPTION

In the figures:

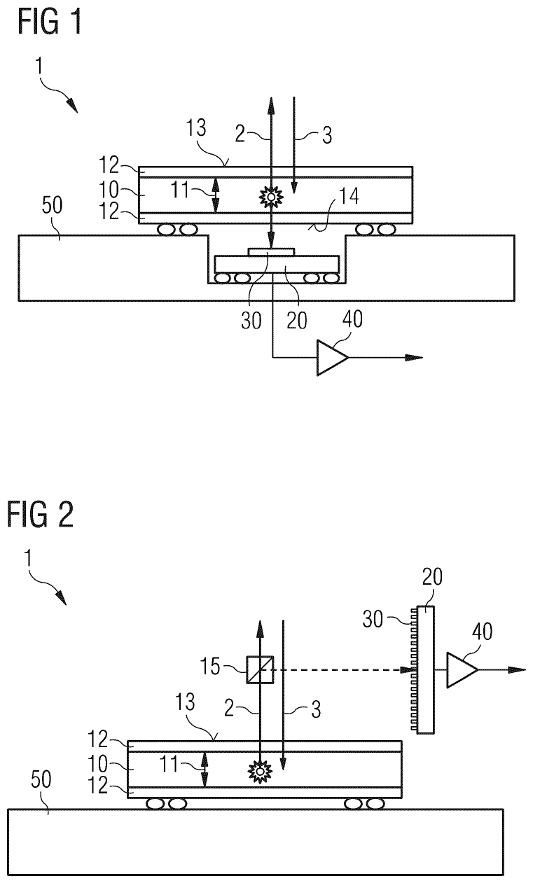

FIGS. 1 to 3 show schematic views of exemplary embodiments of a proposed laser sensor;

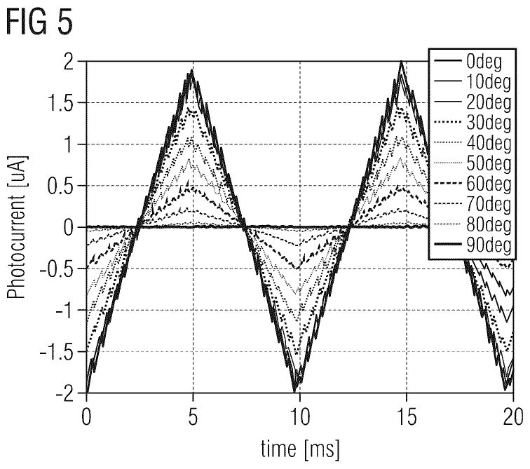

FIG. 4 illustrates the output polarization of a VCSEL employed in a proposed laser sensor;

FIGS. 5 to 9 illustrate the working principle of the linear polarizer according to the improved concept; and

FIG. 10 is a schematic view of an electronic device comprising a proposed laser sensor.

FIG. 1 shows a first exemplary embodiment of a self-mixing interference laser sensor 1 according to the improved concept. The laser sensor 1 comprises a vertical-cavity surface-emitting laser 10. The VCSEL 10 comprises a VCSEL layer structure that is formed by a cavity region 11 that is embedded between two end mirrors realized as distributed Bragg reflectors 12, thus forming a laser cavity in between. The cavity region 11 comprises an electrically pumped gain medium. The DBRs 12 are characterized by a reflectivity close to unity, however, in this embodiment allowing the two-sided emission of light 2 through an emission surface 13 and a further emission surface 14 opposite the emission surface 13. For example, the reflectivity of the DBRs 12 are in the order of 99% at an emission wavelength of the VCSEL 10, e.g. a NIR wavelength from 800 nm to 1000 nm. The reflectivity of the top side DBR 12 facing away from the substrate 50 further allows reflected or scattered light 3 from an object or a scene in the field-of-view of the laser sensor 1 to be reinjected into the cavity of the VCSEL 10 for generating self-mixing interference.

The operating current for current injection into the gain medium is provided by a current source, not shown, that is coupled to the VCSEL and embedded in a substrate body 50 as part of an integrated circuit, or it is external. Said current source is configured to apply a drive current composed of a DC contribution for enabling the lasing of the VCSEL 10 and an AC modulation for modulating the output frequency of the VCSEL 10 in order to scan through regimes in which the conditions for constructive self-mixing interference are fulfilled. For example, the modulation signal, e.g. a saw tooth or triangular signal, can be supplied to the current source by means of a function generator, which likewise can be an integrated component or an external device.

The laser sensor 1 further comprises a photodetector 20 that, in this embodiment, is arranged on or within the substrate 50 and is configured to receive the light of the VCSEL 10 that is emitted through the further emission surface 14. The photodetector 20 can be realized as a photodiode, for instance. In other words, the second output port on the back side of the VCSEL acts as a monitoring port, while the output port on the front side acts as a sensing port. The laser sensor 1 further comprises a linear polarizer 30 that is arranged in front of a photosensitive surface of the photodetector 20 on the optical path such that all emitted light from the further emission surface 14 of the VCSEL 10 passes through the linear polarizer 30 before being detected by the photodetector 20. The linear polarizer 30 can be an absorptive polarizer, e.g. a Polaroid film or a polarizer realized by means of silver nanoparticles embedded in thin glass plates. Alternatively, the linear polarizer 30 can be a beam-splitting polarizer, e.g. a polarizer based on Fresnel reflections or a thin-film polarizer. Linear polarizers themselves are a well-known concept and are not further detailed here.

At sufficiently low driving currents for ensuring single mode operation, constituting an essential requirement for efficient SMI detection, the emitted light of the VCSEL 10 in the lasing fundamental mode is typically linearly polarized.

This polarization is maintained even if the laser is frequency modulated via a modulated component of the driving current. Thus, the linear polarizer 30 can be characterized to predominantly, or exclusively, transmit light that has a polarization angle orthogonal to that of the emitted light 2. In other terms, the linear polarizer has a passing polarization that is rotated by an angle α larger than 0°, e.g. by 90°, with respect to the polarization direction of the emitted light 2. In this way, the photodetector 20 predominantly, or exclusively, receives light with an altered polarization direction with respect to the emitted light 2, the emitted light 2 being particularly altered due to self-mixing interference. Thus, the modulation of the laser frequency, typically also manifesting itself in a corresponding modulation of the output power, can be efficiently removed in the optical domain. In some applications, rotation angles of the linear polarizer of less than 80° can be preferable.

The SMI laser sensor 1 in this embodiment further comprises an evaluation unit 40 that is coupled to the photodetector 20 and configured to receive a photo signal generated based on the detected light. The evaluation unit 40 is configured to determine a signature of self-mixing interference in the photo signal and from this signature can derive and output a measurement signal indicating a distance, relative or absolute, or a velocity or vibration of an object the reflected light 3 is received back from and reinjected into the cavity of the VCSEL 10.

The VCSEL 10 of the laser sensor 1 can further comprise an aperture layer, e.g. an oxide aperture layer, for defining an emission window of the VCSEL 10 and/or for limiting light above a cut-off angle from reentering the cavity. Moreover, the VCSEL 10 can comprise a metallization layer for defining electrical contacts and terminals of the VCSEL 10, for instance. The VCSEL 10 can be arranged on a substrate body 50.

FIG. 2 shows a second exemplary embodiment of a laser sensor 1. Compared to the first embodiment, the main difference is that the VCSEL 10 in this embodiment is characterized by single-sided emission through the emission surface 13 facing away from the substrate 50. This is realized by providing a bottom DBR 12 with a reflectivity close to unity, e.g. 99.9%. In order for the photodetector 20 to monitor the properties of the emitted light 2, a fraction of the emitted light 2 is directed from a main beam path connecting the emission surface 2 and the object or scene to be measured onto a monitoring beam path towards the photodetector 20 and linear polarizer 30. The redirection of a fraction of light can be realized by means of a non-polarizing beam splitter 15 with a fixed ratio of transmission versus reflection. For example, the beam splitter 15 is characterized by a ratio of transmission versus reflection of 90:10 or 99:1. However, other splitting ratios like 50:50 are also easily implementable depending on the requirements of the application. The beam splitter 15 has the further advantage that no reflected or scattered light 3, potentially having a polarization different from the emitted light 2, can reach the photodetector 20.

The linear polarizer 30 in this case is configured as a structured layer arranged on a photosensitive surface of the photodetector 20, the structured layer realizing a Fresnel polarizer.

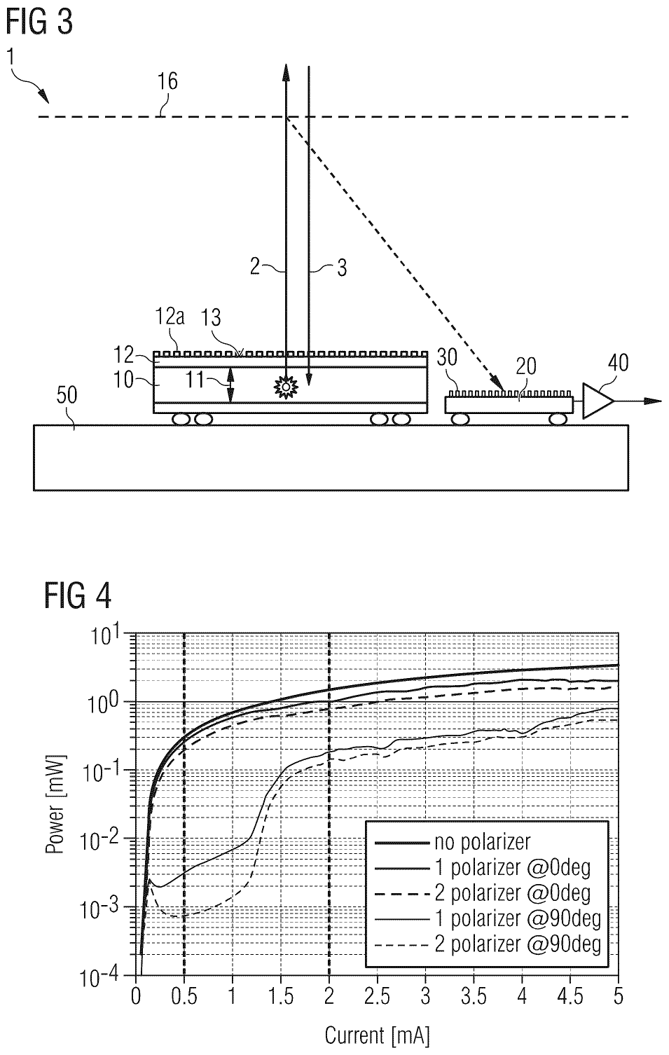

FIG. 3 shows a third exemplary embodiment of a laser sensor 1. Compared to the second embodiment, in this embodiment the laser sensor 1 further comprises a transparent cover 16, e.g. realized as a cover glass plate. In this context “transparent” refers to an emission wavelength of the VCSEL 10. For example, the transparent cover 16 is transparent in the NIR domain of the electromagnetic spectrum. The transparent cover 16, by itself or via a coating on one of its surfaces, can be configured to reflect a portion of the emitted light 2 towards the linear polarizer 30 and the photodetector 20. For example, the amount of reflected light is in the order of 1 to 10% of the total emitted light 2. Also in this case, the reflected or scattered light 3 is prevented from reaching the linear polarizer 30 and the photodetector 20. An advantage of this embodiment is that the photodetector can be arranged next to the VCSEL 10 on a common substrate 50 also including integrated circuitry for electrically connecting the VCSEL 10 to the current source and the photodetector 20 to the evaluation unit 40. The transparent cover 16 can further help to protect the remaining components of the laser sensor 1.

To further ensure a clean output polarization of the VCSEL 10, i.e. to suppress the emission of higher order modes, an optical grating 12a can be arranged on the emission surface 13 of the VCSEL 10. For example, the optical grating 12a is a diffraction grating that is polarization-dependent with a passing polarization matching the linear polarization of the fundamental optical mode of the VCSEL 10. This could ensure a single-mode operation of the VCSEL 10 also at larger driving currents.

FIG. 4 shows an LIV measurement of a VCSEL illustrating the polarization of the light emitted by a VCSEL. For this measurement, the VCSEL output is directly detected by means of a photodetector with a single or a pair of polarizers arranged on an incident side of the photodetector, with passing polarizations either being parallel (0°) or orthogonal (90°) to the polarization of the emitted light 2 (see legend). As can be seen, the detected intensity within the typical operating range of 0.5 mA to 2 mA of a conventional 940 nm emitting VCSEL with a polarizer in parallel configuration indicates that the output of the VCSEL is indeed linearly polarized with the small difference to its total emission (top curve) being due to higher order modes that are, however, strongly suppressed by several orders of magnitude at these operating currents, c.f. signal obtained for the polarizer in orthogonal configuration. The measurement with two polarizers confirms this result.

FIG. 5 shows the photo signal obtained with a laser sensor 1 according to one of the embodiments described above. For this measurement, the laser sensor 1 is directed at a test object from which the emitted light 2 is reflected and reinjected into the laser cavity of the VCSEL 10, while alterations in the output power of the VCSEL are monitored according to the improved concept via a photodetector 20 having a linear polarizer with variable polarization angle arranged in front. For example, this can mean that the emitted light 2 is reflected at or on a test object. The emitted light 2 can be reinjected into the laser cavity of the VCSEL 10. For instance, this can also mean that the linear polarizer with variable polarization angle is arranged in front of the photodetector or on a front of the photodetector. The laser frequency is modulated via a triangular modulation of the driving current applied to the VCSEL 10 with a frequency of 100 Hz in this example. Each time the emitted frequency meets the condition of self-mixing interference of the reinjected light and the light circulating within the cavity, a fringe in the signal occurs, which however in terms of its amplitude is much smaller than the modulation of the laser output power generated by the frequency modulation (c.f. signal at 0 degrees, i.e. with the passing polarization matching the emitted polarization). For example, this can mean that the fringe occurs in the signal. In particular, this can also mean that the amplitude of the fringe can be much smaller than the modulation of the laser output power generated by the frequency modulation. As the passing polarization is detuned to angles up to 90°, i.e. to an orthogonal polarization, the triangular signature strongly decreases, making the fringes due to SMI more prominent in the obtained signal.

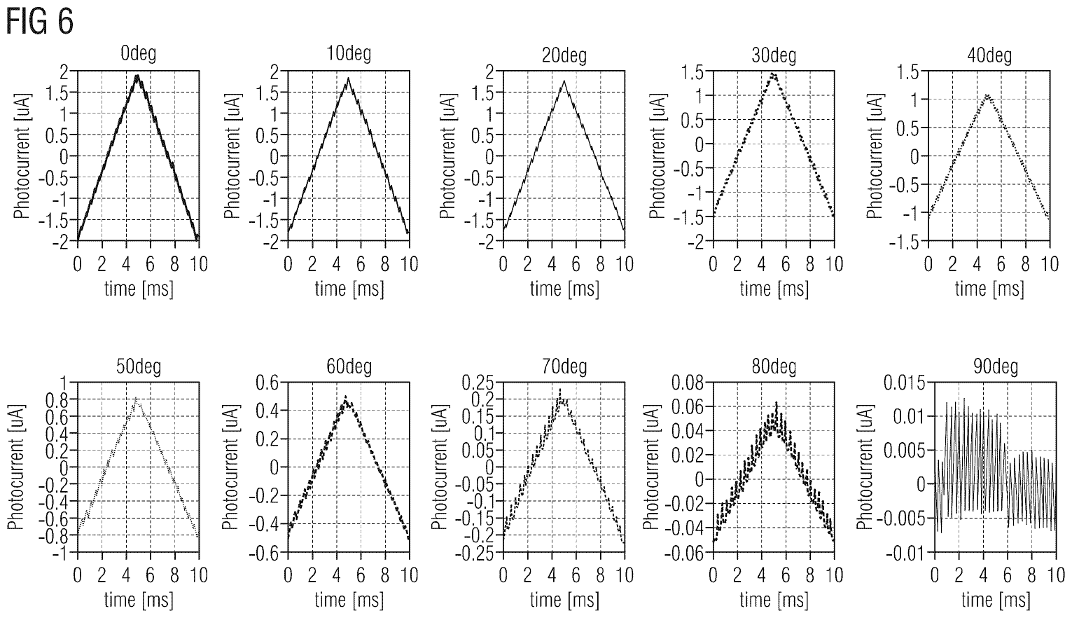

FIG. 6 essentially shows the traces of FIG. 5 in separate panels for emphasizing the increase of the signal contrast of the fringes due to self-mixing interference. As can be seen, a fringe count for determining the absolute or relative distance to the test object can be easily performed if the linear polarizer 30 is cross-polarized, i.e. has a passing polarization orthogonal to a polarization of the emitted light 2. Thus, no further hardware or algorithms are necessary for removing the modulation signal as this is already efficiently realized entirely in the optical domain by means of the linear cross polarizer.

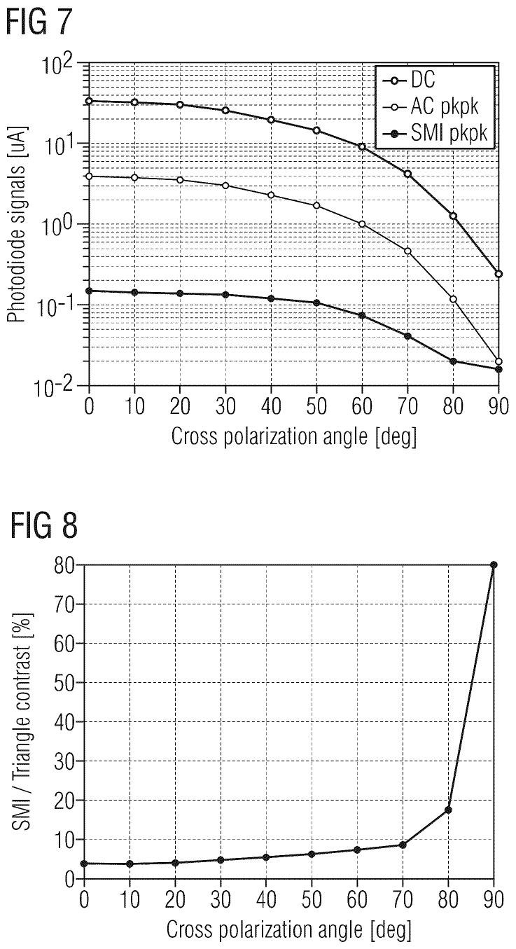

In FIG. 7, the data of FIGS. 5 and 6 is evaluated in terms of the individual contributions to the total signal. As the passing polarization of the linear polarizer 30 is detuned from the output polarization of the VCSEL 10, both the DC component as well as the AC component greatly decrease due to the modulation. The signal due to SMI likewise decreases towards 90°, however, at a much lower rate compared to the DC and AC components.

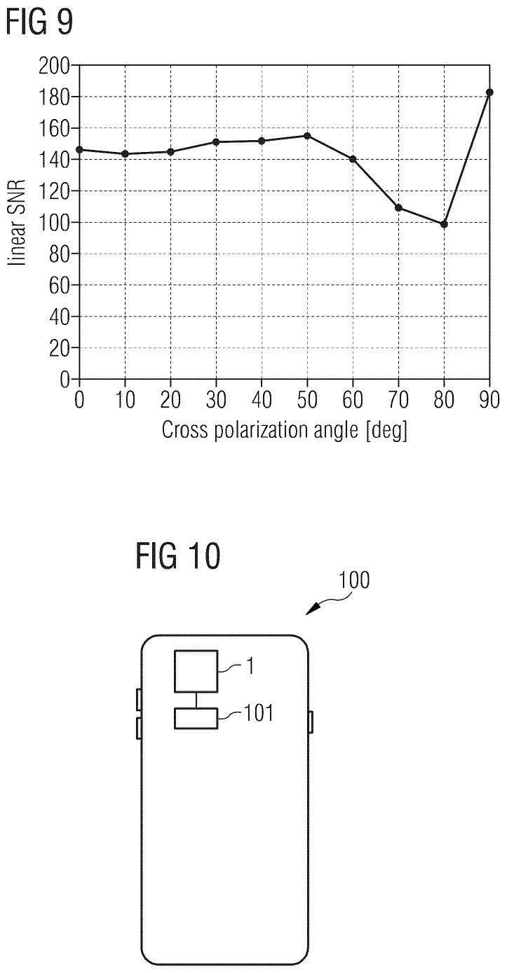

Thus, as illustrated in FIG. 8, a significant enhancement of the contrast, or ratio, between the SMI signal and the triangular background can be achieved, in this case a 20-fold increase of said ratio. This leads to the fact that a significantly enhanced signal-to-noise ratio can be achieved for an optimal detuning of the passing polarization by 90°. Since the DC component is also strongly decreased with the cross polarizer in this configuration, the shot noise limited SNR is not significantly affected even though the SMI amplitude of the signal is decreasing. The SNR of the SMI detection for the measurements of FIGS. 5 and 6 is shown in FIG. 9.

FIG. 10 shows an embodiment of an electronic device 100 comprising an SMI laser sensor 1 according to the improved concept. For example, the electronic device 100 is a smart phone, as depicted. Alternatively, the electronic device can be any portable or mobile electronic device including tablet or laptop computers, augmented or virtual reality glasses, smartwatches or other wearable devices or dedicated distance sensor. Possible applications of an SMI laser sensor 1 in such electronic devices 100 include proximity sensors, ranging applications, eye tracking applications, loud speaker feedback applications etc.

The embodiments of the SMI laser sensor 1, the electronic device 100 and the method of manufacturing an SMI laser sensor 1 disclosed herein have been discussed for the purpose of familiarizing the reader with novel aspects of the idea. Although preferred embodiments have been shown and described, changes, modifications, equivalents and substitutions of the disclosed concepts may be made by one having skill in the art without unnecessarily departing from the scope of the claims.

It will be appreciated that the disclosure is not limited to the disclosed embodiments and to what has been particularly shown and described hereinabove. Rather, features recited in separate dependent claims or in the description may advantageously be combined. Furthermore, the scope of the disclosure includes those variations and modifications which will be apparent to those skilled in the art and fall within the scope of the appended claims.

The term “comprising”, insofar it was used in the claims or in the description, does not exclude other elements or steps of a corresponding feature or procedure. In case that the terms “a” or “an” were used in conjunction with features, they do not exclude a plurality of such features. Moreover, any reference signs in the claims should not be construed as limiting the scope.

This patent application claims the priority of German patent application 10 2022 121 114.2, the disclosure content of which is hereby incorporated by reference.

### REFERENCES

1 laser sensor
2 emitted radiation
3 reflected or scattered radiation
10 vertical cavity surface emitting laser
11 cavity region
12 distributed Bragg reflector
12a optical grating
13, 14 emission surface
15 beam splitter
16 transparent cover
20 photodetector
30 linear polarizer
40 evaluation unit
50 substrate

1. A self-mixing interferometric (SMI) laser sensor, comprising
a vertical cavity surface emitting laser (VCSEL) configured to emit laser radiation with a linear polarization through an emission surface;
a photodetector configured to monitor the laser radiation of the VCSEL; and
a linear polarizer arranged in front of the photodetector such that the laser radiation passes through the linear polarizer before reaching the photodetector;
wherein an orientation of a passing polarization of the linear polarizer differs from the linear polarization of the laser radiation of the VCSEL by an angle different from zero.

2. The SMI laser sensor according to claim 1, wherein the passing polarization of the linear polarizer is orthogonal to the linear polarization of the laser radiation of the VCSEL.

3. The SMI laser sensor according to claim 1, wherein the linear polarizer is an absorptive polarizer.

4. The SMI laser sensor according to claim 1, wherein the linear polarizer is a beam-splitting polarizer.

5. The SMI laser sensor according to claim 1, wherein the photodetector is configured to detect changes in properties of the emitted laser radiation, in particular in the emitted light intensity, due to self-mixing interference.

6. The SMI laser sensor according to claim 1, wherein
the VCSEL is characterized by two-sided emission through the emission surface and a further emission surface opposite the emission surface; and
the photodetector is arranged to capture laser radiation emitted through the further emission surface.

7. The SMI laser sensor according to claim 1, further comprising a beam splitter arranged on or distant from the emission surface and configured to:
transmit a portion of the emitted light to an object or a scene; and
reflect a remaining portion of the emitted light toward the linear polarizer and photodetector.

8. The SMI laser sensor according to claim 1, further comprising a transparent cover arranged distant from the emission surface and configured to:
transmit a portion of the emitted light to an object or a scene; and
reflect a remaining portion of the emitted light toward the linear polarizer and photodetector.

9. The SMI laser sensor according to claim 1, further comprising an evaluation unit coupled to the photodetector and configured to determine an absolute distance, a relative distance, and/or a velocity of an object distant to the SMI laser sensor from a photodetector signal.

10. The SMI laser sensor according to claim 1, further comprising a further linear polarizer arranged in front of the photodetector such that the laser radiation passes through the linear polarizer and the further linear polarizer before reaching the photodetector.

11. The SMI laser sensor according to claim 10, wherein an orientation of a passing polarization of the further linear polarizer equals the orientation of the passing polarization of the linear polarizer.

12. The SMI laser sensor according to claim 1, wherein the orientation of a passing polarization of the linear polarizer is adjustable.

13. The SMI laser sensor according to claim 1, further comprising an optical grating arranged on the emission surface.

14. An electronic device comprising a SMI laser sensor according to claim 1, wherein the SMI laser sensor is configured to measure an absolute distance, a relative distance, and/or a velocity of an object distant from the electronic device in the field-of-view of the SMI laser sensor.

15. A method of manufacturing a self-mixing interferometric (SMI) laser sensor the method comprising:
providing a vertical cavity surface emitting laser (VCSEL) configured to emit laser radiation with a linear polarization through an emission surface;
arranging a photodetector for monitoring the laser radiation of the VCSEL; and
arranging a linear polarizer in front of the photodetector such that the laser radiation passes through the linear polarizer before reaching the photodetector;
wherein an orientation of a passing polarization of the linear polarizer differs from the linear polarization of the laser radiation of the VCSEL by an angle different from zero.
